(19) United States
(12) Patent Application Publication
(10) Pub. No.: US 2015/0250050 A1
(43) Pub. Date: Sep. 3, 2015

(54) EMBEDDED BOARD AND METHOD OF MANUFACTURING THE SAME

(71) Applicant: SAMSUNG ELECTRO-MECHANICS CO., LTD., Suwon-Si (KR)

(72) Inventors: Chang Bo LEE, Suwon-Si (KR); Do Wan Kim, Suwon-si (KR); Soon Jin Cho, Suwon-si (KR)

(73) Assignee: SAMSUNG ELECTRO-MECHANICS CO., LTD., Suwon-Si (KR)

(21) Appl. No.: 14/339,155

(22) Filed: Jul. 23, 2014

(30) Foreign Application Priority Data
Feb. 28, 2014 (KR) 10-2014-0024458

(51) Int. Cl. H05K 1/03; H05K 3/10; H05K 3/32; H05K 3/30; H05K 1/09; H05K 1/11

(52) U.S. Cl. CPC H05K 1/0313; H05K 1/09; H05K 1/115; H05K 3/32; H05K 3/305; H05K 3/10; H05K 2201/0137

(57) ABSTRACT

Disclosed herein are an embedded board and a method of manufacturing the same. According to a preferred embodiment of the present invention, the embedded board includes: an outer layer insulating layer; an electronic device disposed inside the outer layer insulating layer; an outer layer circuit layer formed to protrude from one surface of the outer layer insulating layer; a first via formed on the outer layer insulating layer and electrically connecting the electronic device to the outer layer circuit layer; and a build up layer formed on the other surface of the outer layer insulating layer and including a build up insulating layer and a build up circuit layer.

### CROSS REFERENCE TO RELATED APPLICATION

This application claims the benefit of Korean Patent Application No. 10-2014-0024458, filed on Feb. 28, 2014, entitled “Embedded Board And Method Of Manufacturing The Same” which is hereby incorporated by reference in its entirety into this application.

### BACKGROUND OF THE INVENTION

1. Technical Field

The present invention relates to an embedded board and a method of manufacturing the same.

2. Description of the Related Art

With the increased demand for multi-functional, small and thin cellular phones and electronic devices of information technology (IT), a technology of embedding electronic components, such as ICs, semiconductor chips, active devices and passive devices, into a board so as to meet technological demands has been required. Recently, technologies of embedding components into the board by various methods have been developed.

According to the general component embedded board, a cavity is formed into an insulating layer of the board and electronic components, such as various devices, ICs, and semiconductor chips, are embedded into the cavity. Next, an adhesive resin, such as prepreg, is applied into the cavity and on an insulating layer into which the electronic components are embedded. As described above, the electronic components are fixed and the insulating layer is formed, by applying the adhesive resin.

[Prior Art Document]

[Patent Document]

(Patent Document 1) U.S. Pat. No. 7,886,433

### SUMMARY OF THE INVENTION

The present invention has been made in an effort to provide an embedded board and a method of manufacturing the same capable of improving electrical characteristics.

Further, the present invention has been made in an effort to provide an embedded board having a reduced thickness by removing an unnecessary circuit layer and a method of manufacturing the same.

In addition, the present invention has been made in an effort to provide an embedded board and a method of manufacturing the same capable of easily implementing a fine circuit.

Moreover, the present invention has been made in an effort to provide an embedded board and a method of manufacturing the same capable of reducing a defective rate.

According to a preferred embodiment of the present invention, there is provided an embedded board, including: an outer layer insulating layer; an electronic device disposed inside the outer layer insulating layer; an outer layer circuit layer formed to protrude from one surface of the outer layer insulating layer; a first via formed on the outer layer insulating layer and electrically connecting the electronic device to the outer layer circuit layer; and a build up layer formed on the other surface of the outer layer insulating layer and including a build up insulating layer and a build up circuit layer.

The build up circuit layer may be formed in a multi layer.

One layer of the multilayered build up circuit layer may be formed to protrude from one surface of the build up insulating layer and the other layer thereof may be formed to be embedded in the other surface of the build up insulating layer.

The embedded board may further include: a second via formed on the outer layer insulating layer and electrically connecting the outer layer circuit layer to the build up circuit layer.

The embedded board may further include: a first metal post formed on the outer layer insulating layer and electrically connecting the outer layer circuit layer to the build up circuit layer.

The embedded board may further include: a second metal post formed on one surface of the build up circuit layer; and a third via formed on one surface of the second metal post and electrically connecting the second metal post to the outer layer circuit layer.

The embedded board may further include: a protective layer formed on one surface of the outer layer circuit layer and the outer layer insulating layer and the other surface of the build up layer.

The protective layer may be formed of a solder resist.

The embedded board may further include: an adhesive layer formed between the electronic device and the build up layer.

According to another preferred embodiment of the present invention, there is provided a method of manufacturing an embedded board, including: preparing a carrier member; forming a build up layer including a build up circuit layer and a build up insulating layer on one surface or both surfaces of the carrier member; disposing an electronic device on one surface of the build up layer; forming an outer layer insulating layer on one surface of the build up layer to embed the electronic device; forming an outer layer circuit layer and a first via electrically connecting the outer layer circuit layer to the electronic device on the outer layer insulating layer; and removing the carrier member.

In the forming of the build up layer, the build up circuit layer may be formed in a multi layer.

In the forming of the build up layer, one layer of the multilayered build up circuit layer may be formed to protrude from one surface of the build up insulating layer and the other layer thereof may be formed to be embedded in the other surface of the build up insulating layer.

The disposing of the electronic device may include forming an adhesive layer between the electronic device and the build up layer.

The forming of the outer layer circuit layer and the first via may include forming a second via penetrating through the outer layer insulating layer to electrically connect the outer layer circuit layer to the build up circuit layer.

The method may further include: after the forming of the build up layer, forming a metal post on one surface of the build up circuit layer.

In the forming of the outer layer insulating layer, the outer layer insulating layer may be formed to expose one surface of the metal post to the outside.

In the forming of the outer layer circuit layer and the first via, the outer layer circuit layer may be bonded to one surface of the metal post which is exposed to the outside.

In the forming of the outer layer insulating layer, the outer layer insulating layer may be formed to embed the metal post.

The forming of the outer layer circuit layer and the first via may include forming a third via formed inside the outer layer insulating layer to electrically connect the outer layer circuit layer to a metal post.

The method may further include: after the removing of the carrier member, forming a protective layer formed on one surface of the outer layer circuit layer and the outer layer insulating layer and the other surface of the build up layer.

The protective layer may be formed of a solder resist.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified view illustrating an embedded board according to a first preferred embodiment of the present invention;

FIGS. 2 to 9 are exemplified views illustrating a method of manufacturing the embedded board according to the first preferred embodiment of the present invention;

FIG. 10 is an exemplified view illustrating an embedded board according to a second preferred embodiment of the present invention;

FIGS. 11 to 17 are exemplified views illustrating a method of manufacturing the embedded board according to the second preferred embodiment of the present invention;

FIG. 18 is an exemplified view illustrating an embedded board according to a third preferred embodiment of the present invention; and

FIGS. 19 to 25 are exemplified views illustrating a method of manufacturing the embedded board according to the third preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

### First Preferred Embodiment

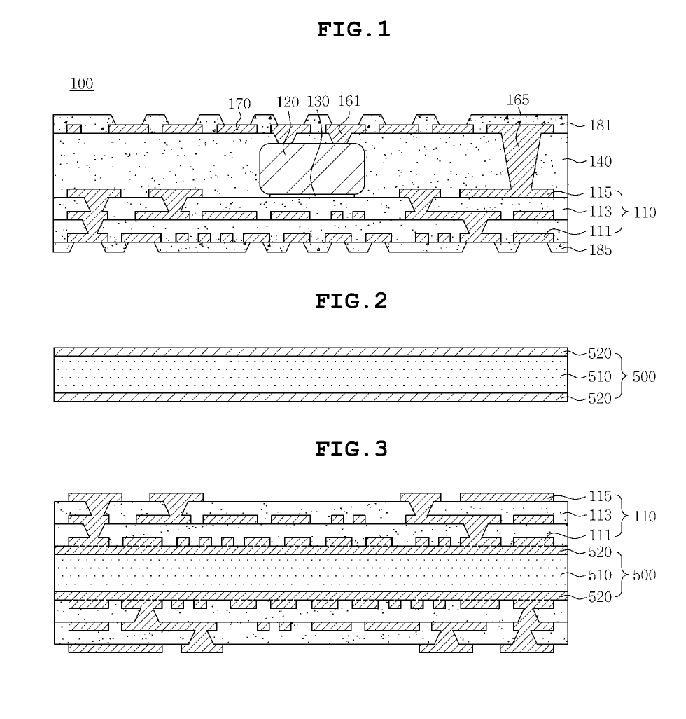

FIG. 1 is an exemplified view illustrating an embedded board according to a first preferred embodiment of the present invention.

Referring to FIG. 1, an embedded board 100 according to a first preferred embodiment of the present invention may include an outer layer insulating layer 140, an electronic device 120, an outer layer circuit layer 170, a first via 161, a second via 165, a build up layer 110, an adhesive layer 130, a first protective layer 181, and a second protective layer 185.

According to the preferred embodiment of the present invention, the outer layer insulating layer 140 may be generally made of a composite polymer resin used as an interlayer insulating material. For example, the outer layer insulating layer 140 may be made of an epoxy based resin, such as prepreg, ajinomoto build up film (ABF), FR-4, bismaleimide triazine (BT), and the like. However, according to the preferred embodiment of the present invention, a material forming the outer layer insulating layer 140 is not limited thereto. The outer layer insulating layer 140 according to the preferred embodiment of the present invention may be selected from the insulating materials known in the circuit board field. The outer layer insulating layer 140 according to the preferred embodiment of the present invention may be formed to have a thickness larger than that of the electronic device 120 disposed therein.

According to the preferred embodiment of the present invention, the electronic device 120 may be disposed inside the outer insulating layer 140. The electronic device 120 may be any of an active device and a passive device. For example, the electronic device 120 may be a multi layer ceramic capacitor (MLCC).

According to the preferred embodiment of the present invention, the outer layer circuit layer 170 may be formed on one surface of the outer layer circuit layer 140 and may be formed to protrude from one surface thereof For example, the outer layer circuit layer 170 may be made of copper (Cu). However, a material forming the outer layer circuit layer 170 is not limited to copper. That is, any material which is used as a conductive material for a circuit in a circuit board field may be applied to the outer layer circuit layer 170 without being limited.

According to the preferred embodiment of the present invention, the first via 161 may be disposed inside the outer layer insulating layer 140. One surface of the first via 161 may be bonded to the outer layer circuit layer 170 and the other surface thereof may be bonded to the electronic device 120. The outer layer circuit layer 170 may be electrically connected to the electronic device 120 through the first via 161.

In the embedded board 100 according to the preferred embodiment of the present invention, the electronic device 120 may be connected to the outer layer circuit layer 170 only through the first via 161. Therefore, an electrical path between the electronic device 120 and the outer layer circuit layer 170 is short and thus signal transmission efficiency may be improved.

According to the preferred embodiment of the present invention, the second via 165 may be disposed inside the outer layer insulating layer 140. One surface of the second via 165 may be bonded to the outer layer circuit layer 170 and the other surface thereof may be bonded to the second build up circuit layer 115. That is, the outer layer circuit layer 170 may be electrically connected to the second build up circuit layer 115 through the second via 165.

The preferred embodiment of the present invention describes, by way of example, that the embedded board 100 is formed with both of the first via 161 and the second via 165, but is not limited thereto. That is, the embedded board 100 may be formed with any one of the first via 161 and the second via 165 according to the selection of those skilled in the art or another position thereof may be further formed with a via.

According to the preferred embodiment of the present invention, the build up layer 110 may be formed on the other surface of the outer layer insulating layer 140. According to the preferred embodiment of the present invention, the build up layer 110 may include a build up insulating layer 113 and the build up circuit layer.

The build up insulating layer 113 may be generally made of the composite polymer resin used as the interlayer insulating material. For example, the build up insulating layer 113 may be made of an epoxy based resin, such as prepreg, ajinomoto build up film (ABF), FR-4, and bismaleimide triazine (BT). However, according to the preferred embodiment of the present invention, a material forming the build up insulating layer 113 is not limited thereto. The build up insulating layer 113 according to the preferred embodiment of the present invention may be selected from the insulating materials known in the circuit board field.

The build up circuit layer may be made of copper (Cu). However, a material forming the build up circuit layer 180 is not limited to copper. That is, any material which is used as a conductive material for a circuit in a circuit board field may be applied to the build up circuit layer without being limited.

According to the preferred embodiment of the present invention, the build up circuit layer may be formed in a multi layer.

For convenience of understanding, the preferred embodiment of the present invention will be described by considering the build up circuit layer formed on one surface of the build up insulating layer 113 as the second build up circuit layer 115 and the build up circuit layer formed on the other surface thereof as a first build up circuit layer 111. FIG. 1 illustrates that the build up circuit layer is formed in three layers, but the preferred embodiment of the present invention is not limited thereto. That is, the build up circuit layer may be formed in a single layer or a multi layer according to the selection of those skilled in the art.

According to the preferred embodiment of the present invention, the second build up circuit layer 115 may be formed to protrude from one surface of the build up insulating layer 113. Therefore, the second build up circuit layer 115 may be embedded in the outer layer insulating layer 140.

Further, the first build up circuit layer 111 formed on the other surface of the build up insulating layer 113 may be formed to be embedded in the build up insulating layer 113.

According to the preferred embodiment of the present invention, an adhesive layer 130 may be formed between the electronic device 120 and the build up layer 110. An adhesion between the electronic device 120 and the build up layer 110 may be improved by the adhesive layer 130. The adhesive layer 130 may be made of a conductive resin or a non-conductive resin. For example, the adhesive layer 130 may be made of an epoxy resin. However, the case in which the adhesive layer 130 is made of the epoxy resin is only an example and therefore is not limited to a material of the adhesive layer 130. That is, the adhesive layer 130 may be made of any material which is used in the circuit board field and has an adhesion.

According to the preferred embodiment of the present invention, a first protective layer 181 may be formed on one surface of the outer layer insulating layer 140 to enclose the outer layer circuit layer 170. Further, the first protective layer 181 may be patterned so that an area connected to the outside in the outer layer circuit layer 170 is exposed to the outside.

Further, the second protective layer 185 may be formed on the other surface of the build up insulating layer 113 to enclose the first build up circuit layer 111. Further, the second protective layer 185 may be patterned so that an area connected to the outside in the first build up circuit layer 111 is exposed to the outside.

According to the preferred embodiment of the present invention, the first protective layer 181 and the second protective layer 185 may protect the embedded board 100 from external environment. For example, the first protective layer 181 and the second protective layer 185 may prevent the outer layer circuit layer 170 and the first build up circuit layer 111 from being oxidized by being in contact with oxygen. Further, the first protective layer 181 and the second protective layer 185 may prevent the outer layer circuit layer 170 and the first build up circuit layer 111 from being applied with solder at the time of soldering. As described above, the first protective layer 181 and the second protective layer 185 may be formed of a solder resist.

The embedded board 100 according to the preferred embodiment of the present invention does not have a structure in which one surface and the other surface thereof are symmetrical with each other based on the electronic device 120 according to the prior art, but an asymmetrical structure in which only a required circuit layer is formed. Therefore, the embedded board 100 according to the preferred embodiment of the present invention does not have an unnecessary circuit layer and has only the required circuit layer and therefore has a thin thickness. Further, the embedded board 100 according to the preferred embodiment of the present invention has a thin thickness and does not have the unnecessary circuit layer, such that an electrical path between outermost layer circuit layers formed at both sides thereof is short, thereby improving electrical characteristics. In this configuration, the outermost layer circuit layers formed at both sides of the embedded board may each be the outer layer circuit layer 140 and the first build up circuit layer 111.

Further, the embedded board 100 according to the preferred embodiment of the present invention has an asymmetrical structure and thus may relatively control a warpage due to external parts (not illustrated) when the external parts (not illustrated) are mounted later. That is, the embedded board 100 having the asymmetrical structure may be warped in an opposite direction to a direction in which the embedded board 100 is warped due to the external parts (not illustrated). Therefore, when the external parts (not illustrated) are mounted on the embedded board 100 and then packaged, the warpage of the package or the embedded board 100 may be improved.

FIGS. 2 to 9 are exemplified views illustrating a method of manufacturing the embedded board according to the first preferred embodiment of the present invention.

Referring to FIG. 2, a carrier member 500 may be prepared.

According to the preferred embodiment of the present invention, the carrier member 500 may be formed by disposing carrier metal layers 520 on a carrier core 510.

According to the preferred embodiment of the present invention, the carrier core 510 is to support the insulating layer, the circuit layer when the insulating layer and the circuit layer are formed, and the like. The carrier core 510 may be made of an insulating material or a metal material.

According to the preferred embodiment of the present invention, the carrier metal layer 520 may be made of copper. However, the material of the carrier metal layer 520 is not limited to copper, and therefore any material which may be used as a conductive material for a circuit in the circuit board field may be applied to the carrier metal layer 520 without being limited.

The preferred embodiment of the present invention illustrates a copper clad laminate structure in which the carrier member 500 includes the carrier metal layer 520, but is not limited thereto. For example, the carrier member 500 may be configured only of the carrier core 510. As described above, the carrier member 500 is used as a support substrate in the circuit board field and may be formed of anything that may be removed later.

Referring to FIG. 3, the build up layer 110 may be formed.

According to the preferred embodiment of the present invention, the build up layer 110 may include the build up insulating layer 113 and a multilayered build up circuit layer. In this configuration, the build up insulating layer 113 has one configuration and is illustrated by reference numeral, but may be one layer or more by a process of forming the multilayered build up circuit layer. For example, when the build up layer 110 includes a build up circuit layer of two layers, the build up insulating layer 113 may be formed in one layer. Further, as illustrated in FIG. 3, when the build up layer 110 includes a build up circuit layer of three layers or more, the build up insulating layer 113 may be formed in two layers or more.

According to the preferred embodiment of the present invention, the build up circuit layer may be formed in a multi layer. Herein, for convenience of explanation, the preferred embodiment of the present invention will be described by considering the build up circuit layer formed on one surface of the build up insulating layer 113 as the second build up circuit layer 115. Further, the preferred embodiment of the present invention will be described by considering the build up circuit layer formed on the other surface of the build up insulating layer 113 as the first build up circuit layer 111. The build up circuit layer of one layer or more may be further formed between the first build up circuit layer 111 and the second build up circuit layer 115 according to the selection of those skilled in the art.

According to the preferred embodiment of the present invention, first, the first build up circuit layer 111 may be formed on a carrier metal layer 520. Next, the build up insulating layer 113 of one layer may be formed so as to embed the first build up circuit layer 111. The first build up circuit layer 111 is formed on a flat carrier member 500 and may be formed in a fine circuit. Next, those skilled in the art may repeatedly form the build up circuit layer and the build up insulating layer 113 as needed. In this case, a via for electrically connecting the build up circuit layers of different layers may also be formed. Next, the second build up circuit layer 115 may be formed on the final build up insulating layer 113. According to the configuration as described above, the first build up circuit layer 111 may be embedded in the build up insulating layer 113 and the second build up circuit layer 115 may be formed to protrude the build up insulating layer 113.

The preferred embodiment of the present invention describes, by way of example, that the build up layers 110 may be formed on both surfaces of the carrier member 500. However, the build up layer 110 may also be formed only on one surface of the carrier member 500.

According to the preferred embodiment of the present invention, a process for forming a circuit is performed on a flat material like the carrier member 500 to easily implement the fine circuit. That is, according to the preferred embodiment of the present invention, it is easy to form the first build up circuit layer 111, which is the outermost layer later, as the fine circuit later.

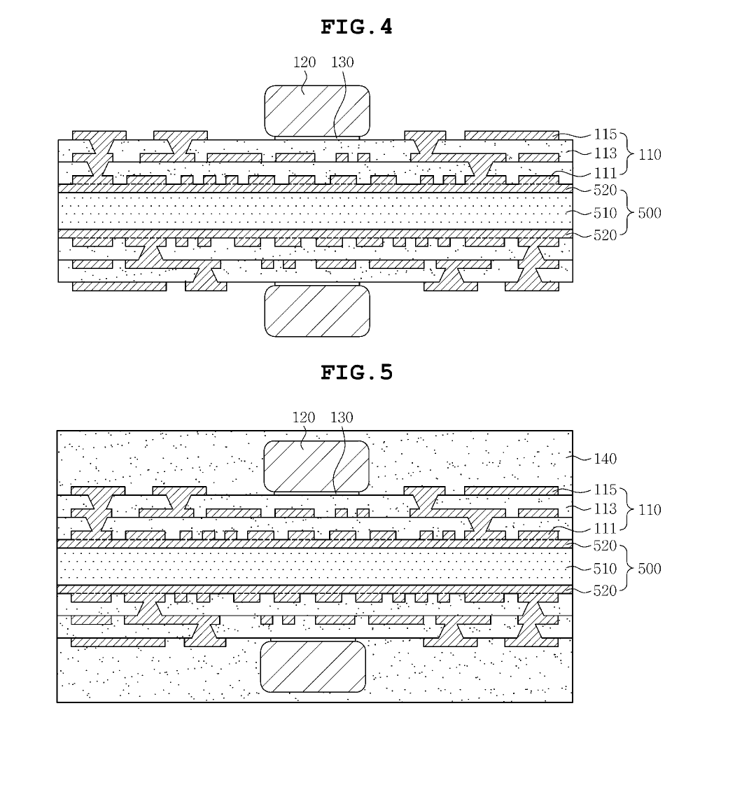

Referring to FIG. 4, the electronic device 120 may be disposed.

According to the preferred embodiment of the present invention, the electronic device 120 may be disposed on one surface of the build up layer 110. In this case, the electronic device 120 may be disposed on one surface of the build up insulating layer 113 or the second build up circuit layer 115.

Further, the adhesive layer 130 may be interposed between the electronic device 120 and the build up layer 110. The adhesive layer 130 may be made of a conductive resin or a non-conductive resin.

For example, the electronic device 120 may be disposed on one surface of the second build up circuit layer 115 and the adhesive layer 130 may be made of the conductive resin. In this case, the electronic device 120 may be electrically connected to the second build up circuit layer 115.

Alternatively, the electronic device 120 may be disposed on one surface of the build up insulating layer 113 and the adhesive layer 130 may be made of the non-conductive resin.

The device 120 according to the preferred embodiment of the present invention may also be any of the active device and the passive device. For example, the electronic device 120 may be a multi layer ceramic capacitor (MLCC).

When the embedded board is manufactured, the defective rate of the process of disposing an electronic device is lower than that of the process of forming a circuit. That is, according to the preferred embodiment of the present invention, the process of forming a build up layer which is the process of forming a circuit having a high defective rate is first performed and then the electronic device is disposed, thereby reducing a manufacturing and process loss.

Referring to FIG. 5, the outer layer insulating layer 140 may be formed.

According to the preferred embodiment of the present invention, the outer layer insulating layer 140 may be formed on one surface of the build up layer 110 to embed the electronic device 120. Further, the outer layer insulating layer 140 may embed the second build up circuit layer 115. The outer layer insulating layer 140 may be generally made of the composite polymer resin used as the interlayer insulating material. For example, the outer layer insulating layer 140 may be made of an epoxy based resin, such as prepreg, ajinomoto build up film (ABF), FR-4, and bismaleimide triazine (BT). However, according to the preferred embodiment of the present invention, a material forming the outer layer insulating layer 140 is not limited thereto. The outer layer insulating layer 140 according to the preferred embodiment of the present invention may be selected from the insulating materials known in the circuit board field. The outer layer insulating layer 140 according to the preferred embodiment of the present invention may be formed to have a thickness larger than that of the electronic device 120 disposed therein.

According to the preferred embodiment of the present invention, the electronic device 120 is first disposed and then the outer layer insulating layer 140 is formed, such that a process of forming a cavity through which the electronic device is mounted according to the prior art may be omitted.

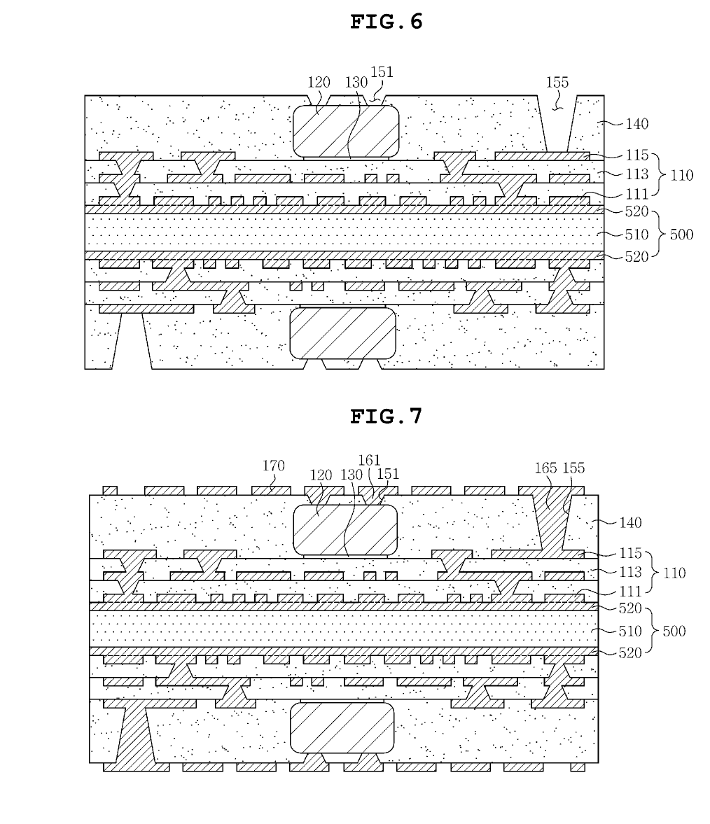

Referring to FIG. 6, a first via hole 151 and a second via hole 155 may be formed.

According to the preferred embodiment of the present invention, the first via hole 151 may be disposed inside the outer layer insulating layer 140 to expose the electronic device 120. Herein, the first via hole 151 may expose an electrode (not illustrated) of the electronic device 120.

Further, the second via hole 155 may be formed on the outer layer insulating layer 140 to expose the second build up circuit layer 115.

According to the preferred embodiment of the present invention, the first via hole 151 and the second via hole 155 may be formed by laser drill or CNC drill. Further, the first via hole 151 and the second via hole 155 may be formed by a typical method of forming a via hole in the circuit board field as well as the laser drill and the CNC drill.

Referring to FIG. 7, the first via 161, the second via 165, and the outer layer circuit layer 170 may be formed.

According to the preferred embodiment of the present invention, the outer layer circuit layer 170 may be formed on one surface of the outer layer insulating layer 140. Further, the outer layer circuit layer 170 may have a structure which protrudes from one surface of the outer layer insulating layer 140.

According to the preferred embodiment of the present invention, the first via 161 may be formed by filling the conductive material in the first via hole 151. Therefore, one surface of the first via 161 may be bonded to the outer layer circuit layer 170 and the other surface thereof may be bonded to the electrode (not illustrated) of the electronic device 120. That is, the first via 161 may electrically connect the outer layer circuit layer 170 to the electronic device 120.

Further, the second via 165 may be formed by filling the conductive material in the second via hole 155. Therefore, one surface of the second via 165 may be bonded to the outer layer circuit layer 170 and the other surface thereof may be bonded to the second build up circuit layer 115. That is, the second via 165 may electrically connect the outer layer circuit layer 170 to the second build up circuit layer 115.

According to the preferred embodiment of the present invention, the first via 161, the second via 165, and the outer layer circuit layer 170 may be formed by the same process. Alternatively, the outer layer circuit layer 170 may be formed by a separate process which is different from the first via 161 and the second via 165. That is, the first via 161 and the second via 165 may be first formed and then the outer layer circuit layer 170 may be formed.

According to the preferred embodiment of the present invention, the method of forming a first via 161, a second via 165, and an outer layer circuit layer 170 may also be any method among the methods of forming a via and a circuit layer known in the circuit board field.

According to the preferred embodiment of the present invention, the electronic device 120 may be electrically connected to the outer layer circuit layer 170 only through the first via 161. That is, the electrical path between the electronic device 120 and the outer layer circuit layer 170 is short and thus signal transmission efficiency may be improved.

The embedded board 100 according to the preferred embodiment of the present invention has an asymmetrical structure and thus may relatively control a warpage due to external parts (not illustrated) which are mounted later. That is, the embedded board 100 having the asymmetrical structure may be warped in an opposite direction to a direction in which the embedded board 100 is warped due to the external parts (not illustrated). Therefore, when the external parts (not illustrated) are mounted on the embedded board 100 and then packaged, the warpage of the package or the embedded board 100 may be improved.

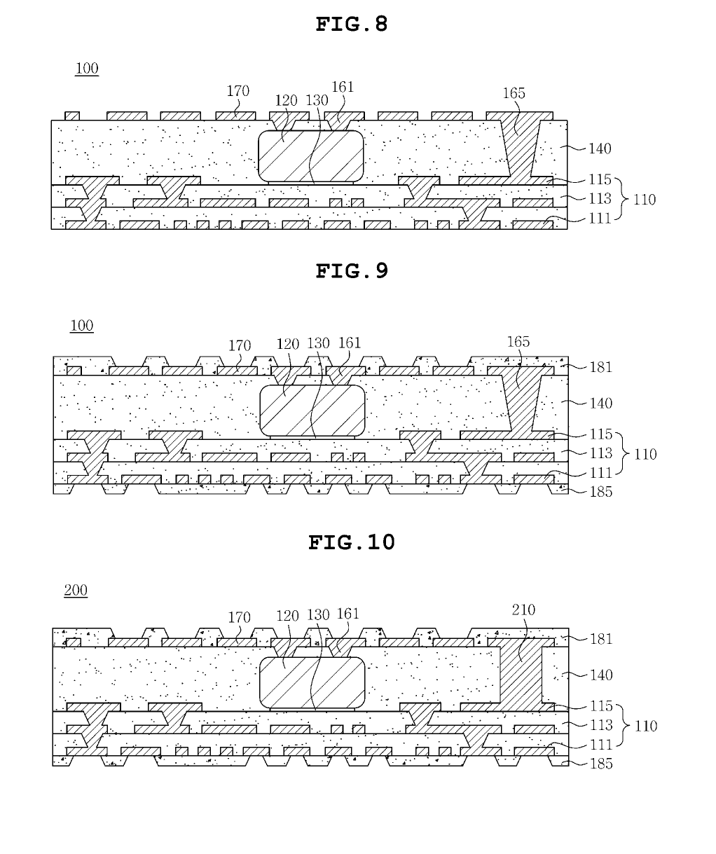

Referring to FIG. 8, the carrier member 500 (FIG. 7) may be removed.

According to the preferred embodiment of the present invention, the carrier member 500

(FIG. 7) is removed and thus the embedded boards 100 which are formed on both surfaces of the carrier member 500 (FIG. 7) may be separated from each other.

For example, first the carrier core 510 (FIG. 7) may be separated from the carrier metal layer 520 (FIG. 7). Next, only the embedded board 100 may remain by removing the carrier metal layer 520 (FIG. 7) using an etching process.

The method of removing a carrier member 500 (FIG. 7) is only by way of example and the method of removing a carrier member 500 (FIG. 7) is not limited thereto. The method of removing a carrier member 500 (FIG. 7) may be changed depending on the structure and material of the carrier member 500 (FIG. 7).

According to the preferred embodiment of the present invention, the embedded boards 100 are formed on both surfaces of the carrier member 500 (FIG. 7) using the carrier member 500 (FIG. 7). That is, according to the preferred embodiment of the present invention, two embedded boards 100 in which the electronic devices 120 are embedded may be simultaneously manufactured.

Referring to FIG. 9, the first protective layer 181 and the second protective layer 185 may be formed.

According to the preferred embodiment of the present invention, a first protective layer 181 may be formed on one surface of the outer layer insulating layer 140 to enclose the outer layer circuit layer 170. Further, the first protective layer 181 may be patterned so that an area connected to the outside in the outer layer circuit layer 170 is exposed to the outside.

Further, the second protective layer 185 may be formed on the other surface of the build up insulating layer 113 to enclose the first build up circuit layer 111. Further, the second protective layer 185 may be patterned so that an area connected to the outside in the first build up circuit layer 111 is exposed to the outside.

According to the preferred embodiment of the present invention, the first protective layer 181 and the second protective layer 185 may protect the embedded board 100 from external environment. For example, the first protective layer 181 and the second protective layer 185 may prevent the outer layer circuit layer 170 and the first build up circuit layer 111 from being oxidized by being in contact with oxygen. Further, the first protective layer 181 and the second protective layer 185 may prevent the outer layer circuit layer 170 and the first build up circuit layer 111 from being applied with solder at the time of soldering. As described above, the first protective layer 181 and the second protective layer 185 may be formed of a solder resist.

### Second Preferred Embodiment

FIG. 10 is an exemplified view illustrating an embedded board according to a second preferred embodiment of the present invention.

Referring to FIG. 10, an embedded board 200 according to a second preferred embodiment of the present invention may include an outer layer insulating layer 140, an electronic device 120, an outer layer circuit layer 170, a first via 161, a first metal post 210, a build up layer 110, an adhesive layer 130, a first protective layer 181, and a second protective layer 185.

According to the preferred embodiment of the present invention, the outer layer insulating layer 140 may be generally made of a composite polymer resin used as an interlayer insulating material.

According to the preferred embodiment of the present invention, the electronic device 120 may be disposed inside the outer insulating layer 140. The electronic device 120 may be any of an active device and a passive device. For example, the electronic device 120 may be a multi layer ceramic capacitor (MLCC).

According to the preferred embodiment of the present invention, the outer layer circuit layer 170 may be formed on one surface of the outer layer circuit layer 140 and may be formed to protrude from one surface thereof Any material which is used as a conductive material for a circuit in a circuit board field may be applied to the outer layer circuit layer 170 without being limited.

According to the preferred embodiment of the present invention, the first via 161 may be formed inside the outer layer insulating layer 140 to electrically connect the electronic device 120 to the outer layer circuit layer 170. In the embedded board 200 according to the preferred embodiment of the present invention, the electronic device 120 may be connected to the outer layer circuit layer 170 only through the first via 161. Therefore, an electrical path between the electronic device 120 and the outer layer circuit layer 170 is short and thus signal transmission efficiency may be improved.

According to the preferred embodiment of the present invention, the first metal post 210 may be disposed inside the outer layer insulating layer 140. One surface of the first metal post 210 may be bonded to the outer layer circuit layer 170 and the other surface thereof may be bonded to the second build up circuit layer 115. That is, the outer layer circuit layer 170 may be electrically connected to the second build up circuit layer 115 through the first metal post 210.

According to the preferred embodiment of the present invention, the build up layer 110 may be formed on the other surface of the outer layer insulating layer 140. According to the preferred embodiment of the present invention, the build up layer 110 may include the build up insulating layer 113 and the build up circuit layer.

The build up insulating layer 113 may be generally made of the composite polymer resin used as the interlayer insulating material.

Further, any material which is used as a conductive material for a circuit in the circuit board field may be applied to the build up circuit layer without being limited.

According to the preferred embodiment of the present invention, the build up circuit layer may be formed in a multi layer.

According to the preferred embodiment of the present invention, the build up circuit layer may include the first build up circuit layer 111 and the second build up circuit layer 115. Further, the build up circuit layer of one layer or more may be further formed between the first build up circuit layer 111 and the second build up circuit layer 115 according to the selection of those skilled in the art.

According to the preferred embodiment of the present invention, the second build up circuit layer 115 may be formed to protrude from one surface of the build up insulating layer 113 and may be embedded in the outer layer insulating layer 140.

Further, the first build up circuit layer 111 may be formed to be embedded in the build up insulating layer 113.

According to the preferred embodiment of the present invention, an adhesive layer 130 may be formed between the electronic device 120 and the build up layer 110. An adhesion between the electronic device 120 and the build up layer 110 may be improved by the adhesive layer 130. The adhesive layer 130 may be made of a conductive resin or a non-conductive resin.

According to the preferred embodiment of the present invention, the first protective layer 181 may be formed on one surface of the outer layer insulating layer 140 to enclose the outer layer circuit layer 170. Further, the second protective layer 185 may be formed on the other surface of the build up insulating layer 113 to enclose the first build up circuit layer 111.

The first protective layer 181 and the second protective layer 185 may be patterned so that the area connected to the outside in the outer layer circuit layer 170 and the first build up circuit layer 110 may be exposed to the outside.

For example, the first protective layer 181 and the second protective layer 185 may be formed of a solder resist.

The embedded board 200 according to the preferred embodiment of the present invention has an asymmetrical structure in which the unnecessary circuit layer is removed and only the required circuit layer is formed and therefore has a thin thickness. Therefore, in the embedded board 200 according to the preferred embodiment of the present invention, the electrical path of electrical signal between the outermost layer circuit layers formed at both sides thereof is short, and the electrical characteristics may be improved.

Further, the embedded board 200 having the asymmetrical structure according to the preferred embodiment of the present invention may be warped in an opposite direction to a direction in which the embedded board 200 is warped due to the external parts (not illustrated) which are mounted later. Therefore, when the external parts (not illustrated) are mounted on the embedded board 200 and then packaged, the warpage of the package or the embedded board 200 may be improved.

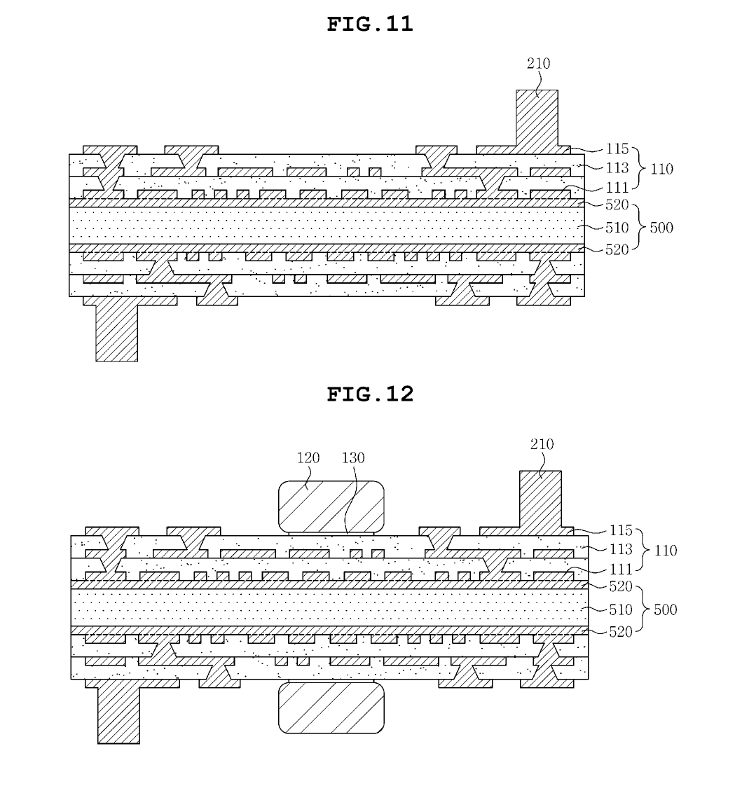

FIGS. 11 to 17 are exemplified views illustrating a method of manufacturing the embedded board according to the second preferred embodiment of the present invention.

In the method of manufacturing an embedded board according to the second preferred embodiment of the present invention, the process of forming the build up layer 110 on the carrier member 500 is the same as the first preferred embodiment of the present invention and therefore the detailed description thereof refers to FIGS. 2 and 3.

Referring to FIG. 11, the first metal post 210 may be formed.

According to the preferred embodiment of the present invention, the first metal post 210 may be disposed inside the second build up circuit layer 115. In this case, one surface of the first metal post 210 may be formed to protrude than one surface of the electronic device 120 which is disposed later.

According to the preferred embodiment of the present invention, first, a plating resist (not illustrated) formed with an opening through which an area formed with the first metal post 210 is opened may be formed in the build up layer 110. Next, an electroplating may be performed on the opening of the plating resist (not illustrated) to form the first metal post 210. After the electroplating, the plating resist (not illustrated) may be removed. However, the method of forming a first metal post 210 is not limited to the electroplating but any method of forming a post in the circuit board field may be used.

Further, the first metal post 210 may be made of a conductive material which is used in the circuit board field. For example, the first metal post 210 may be made of copper (Cu).

Referring to FIG. 12, the electronic device 120 may be disposed.

According to the preferred embodiment of the present invention, the electronic device 120 may be disposed on one surface of the build up layer 110. That is, the electronic device 120 may be disposed on one surface of the build up insulating layer 113 or the second build up circuit layer 115.

Further, the adhesive layer 130 may be interposed between the electronic device 120 and the build up layer 110. The adhesive layer 130 may be made of a conductive resin or a non-conductive resin.

For example, the electronic device 120 may be disposed on one surface of the second build up circuit layer 115 and the adhesive layer 130 may be made of the conductive resin. In this case, the electronic device 120 may be electrically connected to the second build up circuit layer 115.

Alternatively, the electronic device 120 may be disposed on one surface of the build up insulating layer 113 and the adhesive layer 130 may be made of the non-conductive resin.

The device 120 according to the preferred embodiment of the present invention may also be any of the active device and the passive device. For example, the electronic device 120 may be a multi layer ceramic capacitor (MLCC).

When the embedded board is manufactured, the defective rate of the process of disposing an electronic device is lower than that of the process of forming a circuit. That is, according to the preferred embodiment of the present invention, the process of forming a build up layer which is the process of forming a circuit having a high defective rate is first performed and then the electronic device is disposed, thereby reducing a manufacturing and process loss.

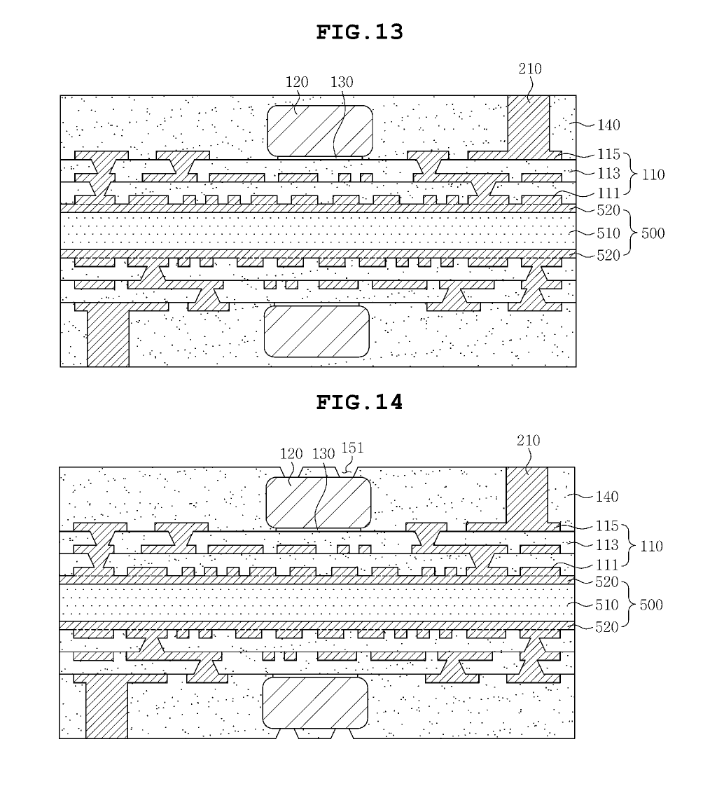

Referring to FIG. 13, the outer layer insulating layer 140 may be formed.

According to the preferred embodiment of the present invention, the outer layer insulating layer 140 may be formed on one surface of the build up layer 110 to embed the electronic device 120 and the second build up circuit layer 115. Further, the outer layer insulating layer 140 may be formed to embed the first metal post 210 and expose one surface of the first metal post 210.

The outer layer insulating layer 140 according to the preferred embodiment of the present invention may be selected from the insulating materials known in the circuit board field. For example, the outer layer insulating layer 140 may be generally made of the composite polymer resin used as the interlayer insulating material. The outer layer insulating layer 140 according to the preferred embodiment of the present invention may be formed to have a thickness larger than that of the electronic device 120 disposed therein.

According to the preferred embodiment of the present invention, the electronic device 120 is first disposed and then the outer layer insulating layer 140 is formed, such that a process of forming a cavity through which the electronic device is mounted according to the prior art may be omitted.

Referring to FIG. 14, the first via hole 151 may be formed.

According to the preferred embodiment of the present invention, the first via hole 151 may be disposed inside the outer layer insulating layer 140 to expose the electrode (not illustrated) of the electronic device 120.

According to the preferred embodiment of the present invention, the first via hole 151 may be formed by laser drill or CNC drill. Further, the first via hole 151 may be formed by a typical method of forming a via hole in the circuit board field as well as the laser drill and the CNC drill.

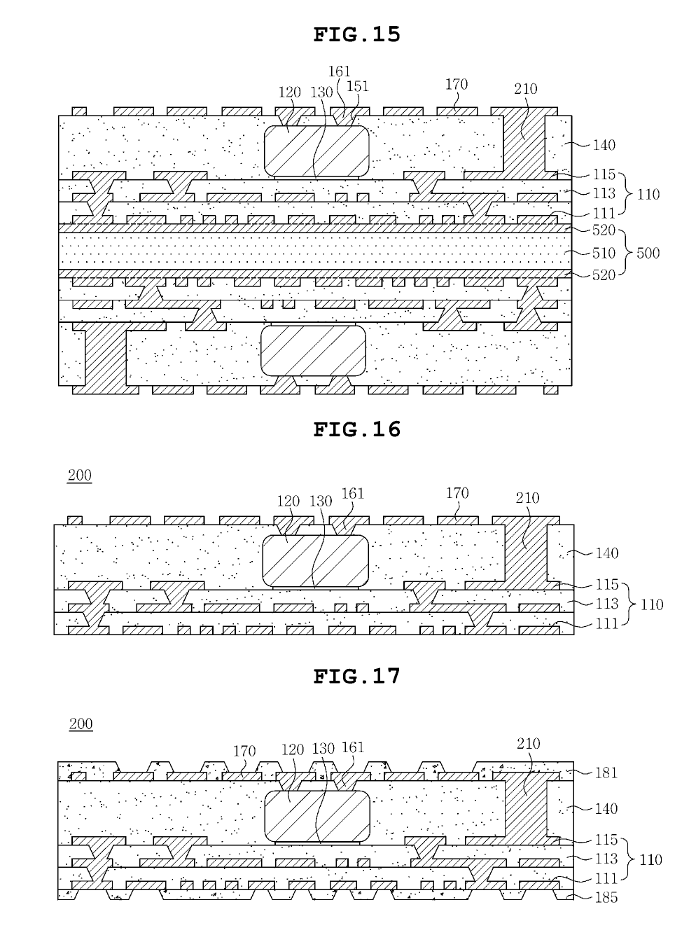

Referring to FIG. 15, the first via 161 and the outer layer circuit layer 170 may be formed.

According to the preferred embodiment of the present invention, the outer layer circuit layer 170 may be formed on one surface of the outer layer insulating layer 140 and may have a structure which protrudes from one surface thereof.

Further, the outer layer circuit layer 170 may be bonded to one surface of the first metal post 210 which is exposed from the outer layer insulating layer 140. Therefore, the outer layer circuit layer 170 may be electrically connected to the second build up circuit layer 115 through the first metal post 210.

According to the preferred embodiment of the present invention, the first via 161 may be formed by filling the conductive material in the first via hole 151. Therefore, one surface of the first via 161 may be bonded to the outer layer circuit layer 170 and the other surface thereof may be bonded to the electrode (not illustrated) of the electronic device 120. That is, the first via 161 may electrically connect the outer layer circuit layer 170 to the electronic device 120.

According to the preferred embodiment of the present invention, the first via 161 and the outer layer circuit layer 170 may be formed by the same process. Alternatively, the outer layer circuit layer 170 may be formed by a separate process which is different from the first via 161. That is, the first via 161 may be first formed and then the outer layer circuit layer 170 may be formed.

According to the preferred embodiment of the present invention, the method of forming a first via 161 and an outer layer circuit layer 170 may be any method among the methods of forming a via and a circuit layer known in the circuit board field.

According to the preferred embodiment of the present invention, the electronic device 120 may be electrically connected to the outer layer circuit layer 170 only through the first via 161. That is, the electrical path between the electronic device 120 and the outer layer circuit layer 170 is short and thus signal transmission efficiency may be improved.

The embedded board 200 according to the preferred embodiment of the present invention has an asymmetrical structure and thus may relatively control a warpage due to external parts (not illustrated) which are mounted later. That is, the embedded board 200 having the asymmetrical structure may be warped in an opposite direction to a direction in which the embedded board 100 is warped due to the external parts (not illustrated). Therefore, when the external parts (not illustrated) are mounted on the embedded board 200 and then packaged, the warpage of the package or the embedded board 200 may be improved.

When the vias connecting the outer layer circuit layer 140 with the electronic device 120 and the second build up circuit layer 115 are each formed, the via hole formed in the second build up circuit layer 115 may not be properly formed due to a step between the electronic device 120 and the second build up circuit layer 115. Further, the via hole formed in the second build up circuit layer 115 is not plated well and thus the defective via may be formed.

However, according to the preferred embodiment of the present invention, the first metal post 210 is first formed prior to forming the first via 161. The foregoing problem may be solved by electrically connecting the outer layer circuit layer 170 with the second build up circuit layer 115 through the first metal post 210.

Referring to FIG. 16, the carrier member 500 (FIG. 15) may be removed.

According to the preferred embodiment of the present invention, the carrier member 500 (FIG. 15) is removed and thus the embedded boards 200 which are formed on both surfaces of the carrier member 500 (FIG. 15) may be separated from each other.

For example, first the carrier core 510 (FIG. 15) may be separated from the carrier metal layer 520 (FIG. 15). Next, only the embedded board 200 may remain by removing the carrier metal layer 520 (FIG. 15) using an etching process.

The method of removing a carrier member 500 (FIG. 15) is only by way of example and the method of removing a carrier member 500 (FIG. 15) is not limited thereto. The method of removing a carrier member 500 (FIG. 15) may be changed depending on the structure and material of the carrier member 500 (FIG. 15).

According to the preferred embodiment of the present invention, two embedded boards 200 in which the electronic devices 120 are embedded may be simultaneously manufactured using the carrier member 500 (FIG. 15).

Referring to FIG. 17, the first protective layer 181 and the second protective layer 185 may be formed.

According to the preferred embodiment of the present invention, the first protective layer 181 may be formed on one surface of the outer layer insulating layer 140 to enclose the outer layer circuit layer 170. Further, the first protective layer 181 may be patterned so that an area connected to the outside in the outer layer circuit layer 170 is exposed to the outside.

Further, the second protective layer 185 may be formed on the other surface of the build up insulating layer 113 to enclose the first build up circuit layer 111. Further, the second protective layer 185 may be patterned so that an area connected to the outside in the first build up circuit layer 111 is exposed to the outside.

According to the preferred embodiment of the present invention, the first protective layer 181 and the second protective layer 185 may prevent the outer layer circuit layer 170 and the first build up circuit layer 111 from being oxidized by being in contact with oxygen. Further, the first protective layer 181 and the second protective layer 185 may prevent the outer layer circuit layer 170 and the first build up circuit layer 111 from being applied with solder at the time of soldering. As described above, the first protective layer 181 and the second protective layer 185 may be formed of a solder resist.

### Third Preferred Embodiment

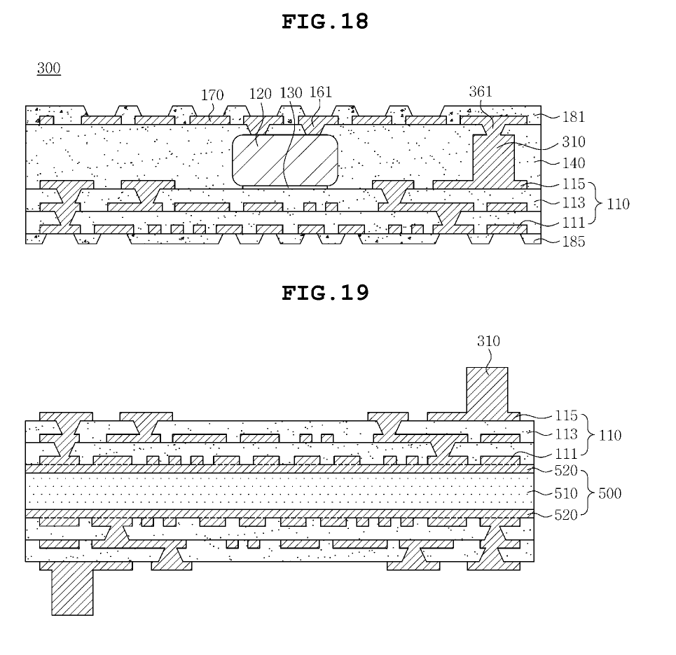

FIG. 18 is an exemplified view illustrating an embedded board according to a third preferred embodiment of the present invention.

Referring to FIG. 18, an embedded board 300 according to a third preferred embodiment of the present invention may include an outer layer insulating layer 140, an electronic device 120, an outer layer circuit layer 170, a first via 161, a second metal post 310, a third via 361, a build up layer 110, an adhesive layer 130, a first protective layer 181, and a second protective layer 185.

According to the preferred embodiment of the present invention, the outer layer insulating layer 140 may be generally made of a composite polymer resin used as an interlayer insulating material.

According to the preferred embodiment of the present invention, the electronic device 120 may be disposed inside the outer insulating layer 140. The electronic device 120 may be any of an active device and a passive device. For example, the electronic device 120 may be a multi layer ceramic capacitor (MLCC).

According to the preferred embodiment of the present invention, the outer layer circuit layer 170 may be formed on one surface of the outer layer circuit layer 140 and may be formed to protrude from one surface thereof Any material which is used as a conductive material for a circuit in a circuit board field may be applied to the outer layer circuit layer 170 without being limited.

According to the preferred embodiment of the present invention, the first via 161 may be formed inside the outer layer insulating layer 140 to electrically connect the electronic device 120 to the outer layer circuit layer 170. In the embedded board 300 according to the preferred embodiment of the present invention, the electronic device 120 may be connected to the outer layer circuit layer 170 only through the first via 161. Therefore, an electrical path between the electronic device 120 and the outer layer circuit layer 170 is short and thus signal transmission efficiency may be improved.

According to the preferred embodiment of the present invention, the second metal post 310 may be disposed inside the outer layer insulating layer 140. One surface of the second metal post 310 may be bonded to the third via 361 and the other surface thereof may be bonded to the second build up circuit layer 115.

According to the preferred embodiment of the present invention, the third via 361 may be disposed inside the outer layer insulating layer 140. Further, one surface of the third via 361 may be bonded to the outer layer circuit layer 170 and the other surface thereof may be bonded to the second metal post 310.

For example, when one surface of the second metal post 310 and one surface of the electronic device 120 are positioned at the same height, the third via 361 may be formed at the same thickness as the first via 161. However, the preferred embodiment of the present invention is not limited to the case in which the first via 161 and the third via 361 have the same thickness. A thickness of the third via 361 may be changed depending on a thickness of the second metal post 310.

According to the preferred embodiment of the present invention, the build up layer 110 may be formed on the other surface of the outer layer insulating layer 140. According to the preferred embodiment of the present invention, the build up layer 110 may include the build up insulating layer 113 and the build up circuit layer.

The build up insulating layer 113 may be generally made of the composite polymer resin used as the interlayer insulating material.

Any material which is used as a conductive material for a circuit in the circuit board field may be applied to the build up circuit layer without being limited.

According to the preferred embodiment of the present invention, the build up circuit layer may be formed in a multi layer.

According to the preferred embodiment of the present invention, the build up circuit layer may include the first build up circuit layer 111 and the second build up circuit layer 115. Further, the build up circuit layer of one layer or more may be further formed between the first build up circuit layer 111 and the second build up circuit layer 115 according to the selection of those skilled in the art.

According to the preferred embodiment of the present invention, the second build up circuit layer 115 may be formed to protrude from one surface of the build up insulating layer 113 and may be embedded in the outer layer insulating layer 140.

Further, the first build up circuit layer 111 may be formed to be embedded in the build up insulating layer 113.

According to the preferred embodiment of the present invention, an adhesive layer 130 may be formed between the electronic device 120 and the build up layer 110. An adhesion between the electronic device 120 and the build up layer 110 may be improved by the adhesive layer 130. The adhesive layer 130 may be made of a conductive resin or a non-conductive resin.

According to the preferred embodiment of the present invention, the first protective layer 181 may be formed on one surface of the outer layer insulating layer 140 to enclose the outer layer circuit layer 170. Further, the second protective layer 185 may be formed on the other surface of the build up insulating layer 113 to enclose the first build up circuit layer 111.

The first protective layer 181 and the second protective layer 185 may be patterned so that the area connected to the outside in the outer layer circuit layer 170 and the first build up circuit layer 111 may be exposed to the outside.

For example, the first protective layer 181 and the second protective layer 185 may be formed of a solder resist.

The embedded board 300 according to the preferred embodiment of the present invention has an asymmetrical structure in which the unnecessary circuit layer is removed and only the required circuit layer is formed and therefore has a thin thickness. Therefore, in the embedded board 300 according to the preferred embodiment of the present invention, the electrical path between the outermost layer circuit layers formed at both sides thereof is short, and the electrical characteristics may be improved.

Further, the embedded board 300 having the asymmetrical structure according to the preferred embodiment of the present invention may be warped in an opposite direction to a direction in which the embedded board 300 is warped due to the external parts (not illustrated) which are mounted later. Therefore, when the external parts (not illustrated) are mounted on the embedded board 300 and then packaged, the warpage of the package or the embedded board 300 may be improved.

FIGS. 19 to 25 are exemplified views illustrating a method of manufacturing the embedded board according to the third preferred embodiment of the present invention.

In the method of manufacturing an embedded board according to the second preferred embodiment of the present invention, the process of forming the build up layer 110 on the carrier member 500 is the same as the first preferred embodiment of the present invention and therefore the detailed description thereof refers to FIGS. 2 and 3.

Referring to FIG. 19, the second metal post 310 may be formed.

According to the third preferred embodiment of the present invention, the second metal post 310 may be formed by the same method and material as the first metal post 210 of FIG. 11 which is the second preferred embodiment of the present invention.

According to the preferred embodiment of the present invention, the second metal post 310 may be formed so that one surface thereof is positioned at the same height as one surface of the electronic device which is disposed later. However, this is only an example and the second metal post 310 may be formed to have various thicknesses according to the selection of those skilled in the art.

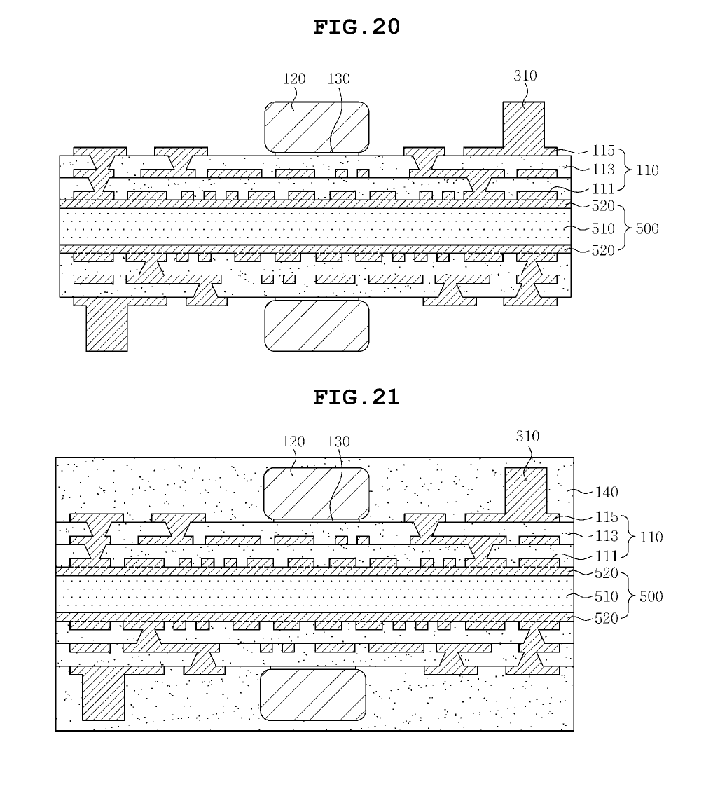

Referring to FIG. 20, the electronic device 120 may be disposed.

According to the preferred embodiment of the present invention, the electronic device 120 may be disposed on one surface of the build up layer 110.

The method of forming an electronic device 120 according to the third preferred embodiment of the present invention may be the same as the method of forming an electronic device 120 according to the second preferred embodiment of the present invention. Therefore, the method of forming an electronic device 120 according to the preferred embodiment of the present invention refers to FIG. 12 which is the second preferred embodiment of the present invention.

Further, likewise the second preferred embodiment of the present invention, even in the third preferred embodiment of the present invention, the adhesive layer 130 may be further disposed between the electronic device 120 and the build up layer 110.

Referring to FIG. 21, the outer layer insulating layer 140 may be formed.

According to the preferred embodiment of the present invention, the outer layer insulating layer 140 may be formed on one surface of the build up layer 110. Further, the outer layer insulating layer 140 may be formed to embed the electronic device 140, the second build up circuit layer 115, and the second metal post 310.

The outer layer insulating layer 140 according to the preferred embodiment of the present invention may be selected from the insulating materials known in the circuit board field. For example, the outer layer insulating layer 140 may be generally made of the composite polymer resin used as the interlayer insulating material. According to the preferred embodiment of the present invention, the outer layer insulating layer 140 may be formed to have a thickness larger than that of the electronic device 120 and the second metal post 310 disposed therein.

According to the preferred embodiment of the present invention, the electronic device 120 is first disposed and then the outer layer insulating layer 140 is formed, such that a process of forming a cavity through which the electronic device is mounted according to the prior art may be omitted.

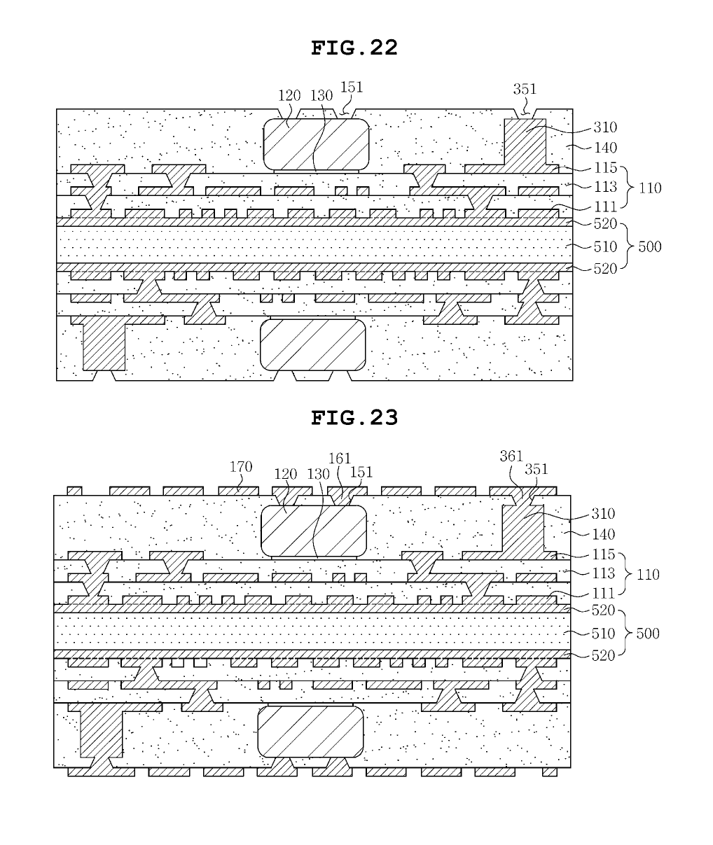

Referring to FIG. 22, the first via hole 151 and the third via hole 351 may be formed.

According to the preferred embodiment of the present invention, the first via hole 151 may be disposed inside the outer layer insulating layer 140 to expose the electronic device 120. Herein, the first via hole 151 may expose an electrode (not illustrated) of the electronic device 120.

Further, the third via hole 351 may be formed on the outer layer insulating layer 140 to expose the second metal post 310.

According to the preferred embodiment of the present invention, the first via hole 151 and the third via hole 351 may be formed by laser drill or CNC drill. Further, the first via hole 151 and the third via hole 351 may be formed by a typical method of forming a via hole in the circuit board field as well as the laser drill and the CNC drill.

Referring to FIG. 23, the first via 161, the third via 361, and the outer layer circuit layer 170 may be formed.

According to the preferred embodiment of the present invention, the outer layer circuit layer 170 may be formed on one surface of the outer layer insulating layer 140. Further, the outer layer circuit layer 170 may have a structure which protrudes from one surface of the outer layer insulating layer 140.

According to the preferred embodiment of the present invention, the first via 161 may be formed by filling the conductive material in the first via hole 151. Therefore, one surface of the first via 161 may be bonded to the outer layer circuit layer 170 and the other surface thereof may be bonded to the electrode (not illustrated) of the electronic device 120. That is, the first via 161 may electrically connect the outer layer circuit layer 170 to the electronic device 120.

Further, the third via 361 may be formed by filling the conductive material in the third via hole 351. Therefore, one surface of the third via 361 may be bonded to the outer layer circuit layer 170 and the other surface thereof may be bonded to the second metal post 310. That is, the outer layer circuit layer 170 and the second build up circuit layer 115 may be electrically connected to each other through the third via 361 and the second metal post 310.

According to the preferred embodiment of the present invention, the method of forming a first via 161, a third via 361, and an outer layer circuit layer 170 may also be any method among the methods of forming a via and a circuit layer known in the circuit board field.

According to the preferred embodiment of the present invention, the electronic device 120 may be electrically connected to the outer layer circuit layer 170 only through the first via 161. That is, the electrical path between the electronic device 120 and the outer layer circuit layer 170 is short and thus signal transmission efficiency may be improved.

The embedded board 300 according to the preferred embodiment of the present invention has an asymmetrical structure and thus may relatively control a warpage due to external parts (not illustrated) which are mounted later. That is, the embedded board 300 having the asymmetrical structure may be warped in an opposite direction to a direction in which the embedded board 100 is warped due to the external parts (not illustrated). Therefore, when the external parts (not illustrated) are mounted on the embedded board 300 and then packaged, the warpage of the package or the embedded board 300 may be improved.

According to the preferred embodiment of the present invention, the step of the area in which the first via 161 and the third via 361 are formed may be reduced by the second metal post 310. Therefore, at the time of forming the third via 361, it is possible to prevent the defect from occurring due to the step.

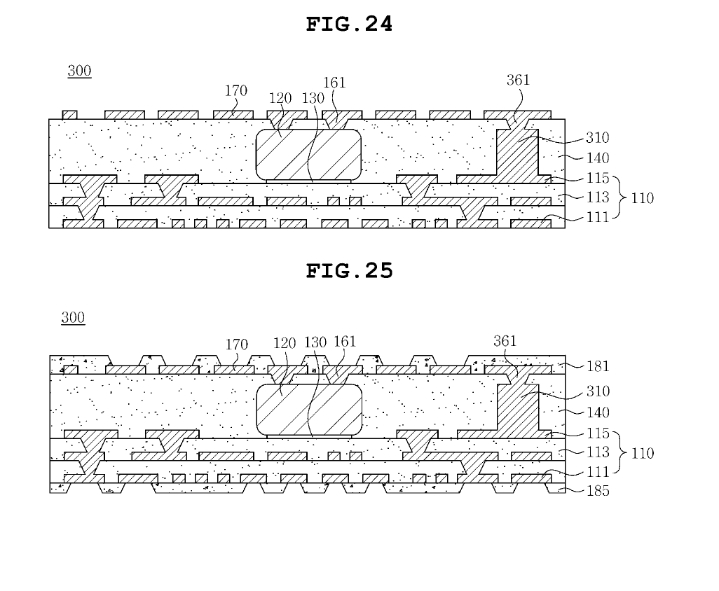

Referring to FIG. 24, the carrier member 500 (FIG. 23) may be removed.

According to the preferred embodiment of the present invention, the carrier member 500 (FIG. 23) is removed and thus the embedded boards 300 which are formed on both surfaces of the carrier member 500 (FIG. 23) may be separated from each other.

For example, first the carrier core 510 (FIG. 23) may be separated from the carrier metal layer 520 (FIG. 23). Next, only the embedded board 300 may remain by removing the carrier metal layer 520 (FIG. 23) using an etching process.

The method of removing a carrier member 500 (FIG. 23) is only by way of example and the method of removing a carrier member 500 (FIG. 23) is not limited thereto. The method of removing a carrier member 500 (FIG. 23) may be changed depending on the structure and material of the carrier member 500 (FIG. 23).

According to the preferred embodiment of the present invention, two embedded boards 300 in which the electronic devices 120 are embedded may be simultaneously manufactured using the carrier member 500 (FIG. 23).

Referring to FIG. 25, the first protective layer 181 and the second protective layer 185 may be formed.

According to the preferred embodiment of the present invention, the first protective layer 181 may be formed on one surface of the outer layer insulating layer 140 to enclose the outer layer circuit layer 170. Further, the first protective layer 181 may be patterned so that an area connected to the outside in the outer layer circuit layer 170 is exposed to the outside.

Further, the second protective layer 185 may be formed on the other surface of the build up insulating layer 113 to enclose the first build up circuit layer 111. Further, the second protective layer 185 may be patterned so that an area connected to the outside in the first build up circuit layer 111 is exposed to the outside.

According to the preferred embodiment of the present invention, the first protective layer 181 and the second protective layer 185 may prevent the outer layer circuit layer 170 and the first build up circuit layer 111 from being oxidized by being in contact with oxygen. Further, the first protective layer 181 and the second protective layer 185 may prevent the outer layer circuit layer 170 and the first build up circuit layer 111 from being applied with solder at the time of soldering. As described above, the first protective layer 181 and the second protective layer 185 may be formed of a solder resist.

In the case of the embedded board, one surface is designed at a low density and the other surface is designed at a high density, based on the electronic device. However, the embedded board according to the prior art has a symmetrical structure in which the number of circuit layers of one surface of the electronic device is the same as the number of circuit layers of the other surface thereof The method of manufacturing an embedded board having the symmetrical structure needs to simultaneously form the circuit layers of one surface and therefore the other surface thereof and the low-density circuit layer also needs to be formed by the method of forming a high-density circuit layer.

However, the embedded board formed according to the preferred embodiment of the present invention has an asymmetrical structure and therefore the circuit layers formed on one surface and the other surface of the electronic device may be formed by an individual process. That is, the one surface of the electronic device may be formed by the method of the low-density circuit layer and the other surface thereof may be formed by the method of the high-density circuit layer. Therefore, when each circuit layer is formed, the method actually meeting a circuit design may be applied and a freedom of design may be improved.

Further, the embedded board having the symmetrical structure according to the prior art is formed so that one surface and the other surface have the same number of circuit layers based on the electronic device, and therefore the unnecessary circuit layer may be formed.

However, the method of manufacturing an embedded board according to the preferred embodiment of the present invention individually forms the circuit layers of one surface and the other surface based on the electronic device, and therefore the formation of the unnecessary circuit layer may be omitted. Therefore, according to the preferred embodiment of the present invention, the embedded board having a thin thickness due to the removal of the unnecessary circuit layer may be formed. Therefore, the embedded board 200 formed as described above does not have the unnecessary circuit layer, such that the electrical path between the outermost layer circuit layers formed at both sides thereof is short, thereby improving the electrical characteristics.

According to the embedded board and the method of manufacturing the same in accordance with the preferred embodiments of the present invention, it is possible to improve the electrical characteristics by removing the unnecessary circuit layer.

According to the embedded board and the method of manufacturing the same in accordance with the preferred embodiments of the present invention, it is possible to reduce the thickness by removing the unnecessary circuit layer.

According to the embedded board and the method of manufacturing the same in accordance with the preferred embodiments of the present invention, it is possible to implement the fine circuit by forming the circuit layer on the flat carrier member.

According to the embedded board and the method of manufacturing the same in accordance with the preferred embodiments of the present invention, it is possible to reduce the defective rate by forming the build up layer and then disposing the electronic devices.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An embedded board, comprising:
an outer layer insulating layer;
an electronic device disposed inside the outer layer insulating layer;
an outer layer circuit layer formed to protrude from one surface of the outer layer insulating layer;
a first via formed on the outer layer insulating layer and electrically connecting the electronic device to the outer layer circuit layer; and
a build up layer formed on the other surface of the outer layer insulating layer and including a build up insulating layer and a build up circuit layer.

2. The embedded board as set forth in claim 1, wherein the build up circuit layer is formed in a multi layer.

3. The embedded board as set forth in claim 2, wherein one layer of the multilayered build up circuit layer is formed to protrude from one surface of the build up insulating layer and the other layer thereof is formed to be embedded in the other surface of the build up insulating layer.

4. The embedded board as set forth in claim 1, further comprising:
a second via formed on the outer layer insulating layer and electrically connecting the outer layer circuit layer to the build up circuit layer.

5. The embedded board as set forth in claim 1, further comprising:
a first metal post formed on the outer layer insulating layer and electrically connecting the outer layer circuit layer to the build up circuit layer.

6. The embedded board as set forth in claim 1, further comprising:
a second metal post formed on one surface of the build up circuit layer; and
a third via formed on one surface of the second metal post and electrically connecting the second metal post to the outer layer circuit layer.

7. The embedded board as set forth in claim 1, further comprising:
a protective layer formed on one surface of the outer layer circuit layer and the outer layer insulating layer and the other surface of the build up layer.

8. The embedded board as set forth in claim 7, wherein the protective layer is formed of a solder resist.

9. The embedded board as set forth in claim 1, further comprising:
an adhesive layer formed between the electronic device and the build up layer.

10. A method of manufacturing an embedded board, comprising:
preparing a carrier member;
forming a build up layer including a build up circuit layer and a build up insulating layer on one surface or both surfaces of the carrier member;
disposing an electronic device on one surface of the build up layer;
forming an outer layer insulating layer on one surface of the build up layer to embed the electronic device;
forming an outer layer circuit layer and a first via electrically connecting the outer layer circuit layer to the electronic device on the outer layer insulating layer; and
removing the carrier member.

11. The method as set forth in claim 10, wherein in the forming of the build up layer, the build up circuit layer is formed in a multi layer.

12. The method as set forth in claim 11, wherein in the forming of the build up layer, one layer of the multilayered build up circuit layer is formed to protrude from one surface of the build up insulating layer and the other layer thereof is formed to be embedded in the other surface of the build up insulating layer.

13. The method as set forth in claim 10, wherein the disposing of the electronic device includes forming an adhesive layer between the electronic device and the build up layer.

14. The method as set forth in claim 10, wherein the forming of the outer layer circuit layer and the first via includes forming a second via penetrating through the outer layer insulating layer to electrically connect the outer layer circuit layer to the build up circuit layer.

15. The method as set forth in claim 10, further comprising:
after the forming of the build up layer, forming a metal post on one surface of the build up circuit layer.

16. The method as set forth in claim 15, wherein in the forming of the outer layer insulating layer, the outer layer insulating layer is formed to expose one surface of the metal post to the outside.

17. The method as set forth in claim 16, wherein in the forming of the outer layer circuit layer and the first via, the outer layer circuit layer is bonded to one surface of the metal post which is exposed to the outside.

18. The method as set forth in claim 15, wherein in the forming of the outer layer insulating layer, the outer layer insulating layer is formed to embed the metal post

19. The method as set forth in claim 18, wherein the forming of the outer layer circuit layer and the first via includes forming a third via formed inside the outer layer insulating layer to electrically connect the outer layer circuit layer to a metal post.

20. The method as set forth in claim 10, further comprising:
after the removing of the carrier member, forming a protective layer formed on one surface of the outer layer circuit layer and the outer layer insulating layer and the other surface of the build up layer.

21. The method as set forth in claim 20, wherein the protective layer is formed of a solder resist.
